(19) United States
(12) Patent Application Publication
(10) Pub. No.: US 2026/0318957 A1
(43) Pub. Date: Oct. 15, 2026

(54) INTEGRATED CURRENT SENSOR

(71) Applicant: Allegro MicroSystems, LLC, Manchester, NH (US)

(72) Inventors: Loïc André Messier, Vanzy (FR); Maxime Rioult, Massy (FR); Jamie Haas, Concord, NH (US); Ronald Lehndorff, Mainz (DE); Alexander Latham, Harvard, MA (US); Hernán D. Romero, Buenos Aires (AR); Alejandro Gabriel Milesi, Buenos Aires (AR); Andrea Foletto, Biella (IT); Paul A. David, Bow, NH (US); Vijay Mangtani, Nashua, NH (US); Michael C. Doogue, Bedford, NH (US); William P. Taylor, Amherst, NH (US)

(73) Assignee: Allegro MicroSystems, LLC, Manchester, NH (US)

(21) Appl. No.: 19/718,271

(22) Filed: Jun. 24, 2026

Related U.S. Application Data
(63) Continuation-in-part of application No. 18/818,749, filed on Aug. 29, 2024, now Pat. No. 12,716,918.

(51) Int. Cl. G01R 15/20; G01R 19/00

(52) U.S. Cl. CPC G01R 15/207; G01R 19/0092

(57) ABSTRACT

A current sensor can include a die, a primary current path to carry a primary current through the sensor, and a plurality of magnetic field sensors for sensing current flow along the primary current path. The primary current path can include one or more inlet pillars through which the primary current can enter the die, one or more outlet pillars through which the primary current can exit the die, and an internal conductor coupled between the inlet and outlet pillars. The magnetic field sensors can include one or more magnetic field sensors for sensing the primary current flowing through the inlet pillar, one or more magnetic field sensors for sensing the primary current flowing through the outlet pillar, and one or more magnetic field sensors for sensing the primary current flowing through the inlet pillar, the outlet pillar, the internal conductor, or any combination thereof.

### CROSS-REFERENCE TO RELATED APPLICATIONS

This application is a continuation-in-part, and claims the benefit, of U.S. patent application Ser. No. 18/818,749 filed on Aug. 29, 2024, which is incorporated herein by reference in its entirety.

### BACKGROUND

Current sensors, such as those used to monitor small motors or other robotic joint actuators, typically require high precision but can be subject to various forms of error. For example, in many cases such current sensors are physically separate from and/or arranged around current flow paths. Any movement between the sensor itself and the current flow path, such as due to heat and/or vibration, can cause errors in sensing the current flow. Furthermore, outside interference can also cause errors in sensing the current flow.

### SUMMARY

A current sensor according to the disclosure can be embodied in or on a current sensor die. The current sensor can route current through the die, such as using low resistance metal pillars. For example, the die of the current sensor can include a current path through the die and one or more magnetic field sensors disposed in a fixed relationship to the current path, which can eliminate any movement between the magnetic field sensors and the current path. The current sensor can include shielding to reduce or eliminate outside interference. Thus, a current sensor according to the disclosure can provide high precision current sensing with low resistance.

A current sensor according to the disclosure can include a die, a primary current path to carry a primary current through the sensor, or die, a plurality of magnetic field sensors for sensing current flow along the primary current path, or any combination thereof. The primary current path can include one or more inlet pillars through which the primary current can enter the die, one or more outlet pillars through which the primary current can exit the die, an internal conductor coupled between the inlet and outlet pillars, or any combination thereof. The internal conductor can be disposed within the die. Any or all of the pillars can be coupled to a field effect transistor and/or a lead frame.

The magnetic field sensors can include one or more magnetic field sensors for sensing the primary current flowing through the inlet pillar, one or more magnetic field sensors for sensing the primary current flowing through the outlet pillar, one or more magnetic field sensors for sensing the primary current flowing through the internal conductor, or any combination thereof. For example, the magnetic field sensors can include a first magnetic field sensor for sensing the primary current flowing through the inlet pillar, a second magnetic field sensor for sensing the primary current flowing through the outlet pillar, a third magnetic field sensor disposed between the inlet pillar and the outlet pillar and for sensing the primary current flowing through the inlet pillar, the outlet pillar, the internal conductor, or any combination thereof.

Any or all of the magnetic field sensors can have parallel axes of sensitivity. For example, the first magnetic field sensor can have a first axis of sensitivity and the second magnetic field sensor can have a second axis of sensitivity. The first axis of sensitivity and the second axis of sensitivity can be aligned parallel with one another. Similarly, the third magnetic field sensor can have a third axis of sensitivity, which can be aligned parallel to the first axis of sensitivity and/or the second axis of sensitivity.

In some embodiments, the inlet pillar can include a plurality of inlet pillars and/or the outlet pillar can include a plurality of outlet pillars. The plurality of inlet pillars can be linearly aligned with one another. The plurality of outlet pillars can be linearly aligned with one another. The inlet pillars can be aligned in parallel with the outlet pillars. The internal conductor can include one or more conductors coupling the inlet pillars and the outlet pillars. In some embodiments, the internal conductor can be a single conductor coupling each of the inlet pillars and the outlet pillars.

In some embodiments, the first magnetic field sensor can be or include a single magnetic field sensing element spanning the plurality of inlet pillars and having an axis of sensitivity aligned parallel to the plurality of inlet pillars. The second magnetic field sensor can be or include a single magnetic field sensing element spanning the plurality of outlet pillars and having an axis of sensitivity aligned parallel to the plurality of outlet pillars. The third magnetic field sensor can be or include a single magnetic field sensing element spanning the plurality of inlet pillars and/or the plurality of outlet pillars and having an axis of sensitivity aligned parallel to the plurality of inlet pillars and/or the plurality of outlet pillars.

In some embodiments, the first magnetic field sensor can be or include a plurality of magnetic field sensing elements, which can span the plurality of inlet pillars, can be linearly aligned parallel to the plurality of inlet pillars, can have an axis of sensitivity aligned parallel to the plurality of inlet pillars, or any combination thereof. The second magnetic field sensor can be or include a plurality of magnetic field sensing elements, which can span the plurality of outlet pillars, can be linearly aligned parallel to the plurality of outlet pillars, can have an axis of sensitivity aligned parallel to the plurality of outlet pillars, or any combination thereof. The third magnetic field sensor can be or include a first plurality of magnetic field sensing elements, which can span the plurality of inlet pillars, can be linearly aligned parallel to the plurality of inlet pillars, can have an axis of sensitivity aligned parallel to the plurality of inlet pillars, or any combination thereof. In some embodiments, the third magnetic field sensor can be or include a second plurality of magnetic field sensing elements, which can span the plurality of outlet pillars, can be linearly aligned parallel to the plurality of outlet pillars, can have an axis of sensitivity aligned parallel to the plurality of outlet pillars, or any combination thereof. The first plurality of magnetic field sensing elements can be laterally spaced apart from the second plurality of magnetic field sensing elements.

In some embodiments, the first magnetic field sensor can be or include a first magnetic field sensing element and a second magnetic field sensing element. The first magnetic field sensing element can span a portion of the plurality of inlet pillars and/or the second magnetic field sensing element can span another portion of the plurality of inlet pillars. The first and second magnetic field sensing elements can be linearly aligned parallel to the plurality of inlet pillars and/or can have an axis of sensitivity aligned parallel to the plurality of inlet pillars.

In some embodiments, the second magnetic field sensor can be or include a third magnetic field sensing element and a fourth magnetic field sensing element. The third magnetic field sensing element can span a portion of the plurality of outlet pillars and/or the fourth magnetic field sensing element can span another portion of the plurality of outlet pillars. The third and fourth magnetic field sensing elements can be linearly aligned parallel to the plurality of outlet pillars and/or can have an axis of sensitivity aligned parallel to the plurality of outlet pillars.

In some embodiments, the third magnetic field sensor can be or include a fifth magnetic field sensing element and a sixth magnetic field sensing element. The fifth magnetic field sensing element can span the first portion of the plurality of inlet pillars and/or the sixth magnetic field sensing element can span the second portion of the plurality of inlet pillars. The fifth and sixth magnetic field sensing elements can be linearly aligned parallel to the plurality of inlet pillars. The fifth and sixth magnetic field sensing elements can have an axis of sensitivity aligned parallel to the plurality of inlet pillars and/or the plurality of outlet pillars.

Any or all of the magnetic field sensing elements can be coupled in a bridge. For example, the first magnetic field sensing element and the third magnetic field sensing element can be coupled between a supply connection and a first output of the bridge, the sixth magnetic field sensing element can be coupled between the supply connection and a second output of the bridge, the fifth magnetic field sensing element can be coupled between the first output and a ground connection, the second magnetic field sensing element and the fourth magnetic field sensing element can be coupled between the second output and the ground connection, or any combination thereof.

In some embodiments, the first magnetic field sensor can be or include a first plurality of magnetic field sensing elements and a second plurality of magnetic field sensing elements, the second magnetic field sensor can be or include a third plurality of magnetic field sensing elements and a fourth plurality of magnetic field sensing elements, the third magnetic field sensor can be or include a fifth plurality of magnetic field sensing elements and a sixth plurality of magnetic field sensing elements, or any combination thereof. The first plurality of magnetic field sensing elements can span a first portion of the plurality of inlet pillars, the second plurality of magnetic field sensing elements can span a second portion of the plurality of inlet pillars, the third plurality of magnetic field sensing elements can span a third portion of the plurality of outlet pillars, the fourth plurality of magnetic field sensing elements can span a fourth portion of the plurality of outlet pillars, the fifth plurality of magnetic field sensing elements can span the first portion of the plurality of inlet pillars and/or the third portion of the plurality of outlet pillars, the sixth plurality of magnetic field sensing elements can span the second portion of the plurality of inlet pillars and/or the fourth portion of the plurality of outlet pillars, or any combination thereof. The first plurality of magnetic field sensing elements and the second plurality of magnetic field sensing elements can be linearly aligned, such as parallel to the plurality of inlet pillars. The third plurality of magnetic field sensing elements and the fourth plurality of magnetic field sensing elements can be linearly aligned, such as parallel to the plurality of outlet pillars. The fifth plurality of magnetic field sensing elements and sixth plurality of magnetic field sensing elements can be linearly aligned, such as parallel to the plurality of inlet pillars. Any of all of the magnetic field sensing elements can have an axis of sensitivity aligned parallel to the plurality of inlet pillars and/or the outlet pillars.

In some embodiments, any of all of the magnetic field sensing elements can be coupled in a bridge. For example, the first plurality of magnetic field sensing elements and the third plurality of magnetic field sensing elements can be coupled between a supply connection and a first output of the bridge, the sixth plurality of magnetic field sensing elements can be coupled between the supply connection and a second output of the bridge, the fifth plurality of magnetic field sensing elements can be coupled between the first output and a ground connection, the second plurality of magnetic field sensing elements and the fourth plurality of magnetic field sensing elements can be coupled between the second output and the ground connection, or any combination thereof.

In some embodiments, one or more electric field shields can be disposed between any or all of the magnetic field sensors and the internal conductor, above the magnetic field sensors, below the magnetic field sensors, surrounding any or all of the magnetic field sensors, surrounding any or all of the pillars, or any combination thereof. For example, a first electric field shield can be disposed between any or all of the magnetic field sensors and the internal conductor and a second electric field shield can be disposed on an opposing side of the magnetic field sensors as the first electric field shield.

A current sensor according to the disclosure can include a primary current path to carry a primary current. The primary current path can include a first inlet pillar, a second inlet pillar, a first outlet pillar, a second outlet pillar, an internal conductor coupled between the inlet and outlet pillars, or any combination thereof. The current sensor can also include a first plurality of magnetic field sensing elements disposed surrounding the first inlet pillar for sensing the primary current flowing through the first inlet pillar, a second plurality of magnetic field sensing elements disposed surrounding the second inlet pillar for sensing the primary current flowing through the second inlet pillar, a third plurality of magnetic field sensing elements disposed surrounding the first outlet pillar for sensing the primary current flowing through the first outlet pillar, a fourth plurality of magnetic field sensing elements disposed surrounding the second outlet pillar for sensing the primary current flowing through the second outlet inlet pillar, or any combination thereof.

In some embodiments, the magnetic field sensing elements can be electrically coupled in a bridge. For example, the first plurality of magnetic field sensing elements can be coupled between a supply connection and a first output of the bridge, the second plurality of magnetic field sensing elements can be coupled between the first output and a ground connection of the bridge, the third plurality of magnetic field sensing elements can be coupled between the supply connection and a second output of the bridge, the fourth plurality of magnetic field sensing elements can be coupled between the second output and the ground connection, or any combination thereof.

In some embodiments, any or all of the inlet pillars and/or outlet pillars can be aligned in parallel with a Z-axis. Some of the first plurality of magnetic field sensing elements can be aligned with their axis of sensitivity parallel to an X-axis and/or some of the first plurality of magnetic field sensing elements can be aligned with their axis of sensitivity parallel to a Y-axis. Some of the second plurality of magnetic field sensing elements can be aligned with their axis of sensitivity parallel to an X-axis and/or some of the second plurality of magnetic field sensing elements can be aligned with their axis of sensitivity parallel to a Y-axis. Some of the third plurality of magnetic field sensing elements can be aligned with their axis of sensitivity parallel to an X-axis and/or some of the third plurality of magnetic field sensing elements can be aligned with their axis of sensitivity parallel to a Y-axis. Some of the fourth plurality of magnetic field sensing elements can be aligned with their axis of sensitivity parallel to an X-axis and/or some of the fourth plurality of magnetic field sensing elements can be aligned with their axis of sensitivity parallel to a Y-axis. The X-axis can be orthogonal to the Z-axis and/or the Y-axis, which can be orthogonal to the Z-axis.

A current sensor according to the disclosure can include a primary current path to carry a primary current, which can include one or more inlet pillars, one or more outlet pillars, one or more vertical interconnect access (via), such as a through-silicon via (TSV), coupled between the inlet and outlet pillars, or any combination thereof. The current sensor can also include a plurality of magnetic field sensing elements disposed surrounding the TSV for sensing the primary current flowing through the TSV. In some embodiments, the primary current path can include a plurality of primary current paths and the plurality of magnetic field sensing elements can be disposed surrounding any or all of the primary current paths. In at least one embodiment, any or all of the primary current paths can be aligned in parallel with a Z-axis, some of the plurality of magnetic field sensing elements can be aligned with their axis of sensitivity parallel to an X-axis, and some of the plurality of magnetic field sensing elements can be aligned with their axis of sensitivity parallel to a Y-axis. The X-axis can be orthogonal to the Z-axis and/or the Y-axis, which can be orthogonal to the Z-axis.

A current sensor according to the disclosure can include a primary current path to carry a primary current, which can include a first inlet pillar, a second inlet pillar, an inlet column, an inlet redistribution layer electrically coupled between the inlet pillars and the inlet column, a first outlet pillar, a second outlet pillar, an outlet column, an outlet redistribution layer electrically coupled between the outlet pillars and the outlet column, an internal conductor electrically coupled between the inlet and outlet columns, or any combination thereof. The current sensor can also include a first magnetic field sensor for sensing the primary current flowing through the inlet column and/or the inlet redistribution layer, a second magnetic field sensor for sensing the primary current flowing through the outlet column and/or the outlet redistribution layer, a third magnetic field sensor disposed between the inlet column and the outlet column for sensing the primary current flowing through the columns and/or the internal conductor, or any combination thereof. The columns can be aligned in parallel with the pillars. The redistribution layers can be aligned in parallel with the internal conductor. Any or all of the columns can be or include vias.

It should be appreciated that individual elements of different embodiments described herein may be combined to form other embodiments not specifically set forth above. Various elements, which are described in the context of a single embodiment, may also be provided separately or in any suitable sub-combination. It should also be appreciated that other embodiments not specifically described herein are also within the scope of the following claims.

### BRIEF DESCRIPTION OF THE DRAWINGS

The manner of making and using the disclosed subject matter may be appreciated by reference to the detailed description in connection with the drawings, in which like reference numerals identify like elements.

FIG. 1 is simplified diagram of one embodiment of a current sensor according to the disclosure.

FIG. 2 is a perspective view of select components of one embodiment of a current sensor according to the disclosure.

FIG. 3 is a sectional view of select components of one embodiment of a current sensor according to the disclosure.

FIG. 4 is a simplified diagram of select components of one embodiment of a current sensor according to the disclosure.

FIG. 5 is a schematic of the current sensor of FIG. 4.

FIG. 6 is a sectional view of select components of another embodiment of a current sensor according to the disclosure.

FIG. 7 is a sectional view of select components of yet another embodiment of a current sensor according to the disclosure.

FIG. 8 is a sectional view of select components of still another embodiment of a current sensor according to the disclosure.

FIG. 9 is a sectional view of select components of another embodiment of a current sensor according to the disclosure.

FIG. 10 is a sectional view of select components of yet another embodiment of a current sensor according to the disclosure.

FIG. 11 is a sectional view of select components of still another embodiment of a current sensor according to the disclosure.

FIG. 12 is a sectional view of select components of another embodiment of a current sensor according to the disclosure.

FIG. 13 is a sectional view of select components of yet another embodiment of a current sensor according to the disclosure.

FIG. 14 is a simplified diagram of select components of one embodiment of a current sensor according to the disclosure.

FIG. 15 is a schematic of the current sensor of FIG. 14.

FIG. 16 is a simplified diagram of select components of one embodiment of a current sensor according to the disclosure.

FIG. 17 is a schematic of the current sensor of FIG. 16.

FIG. 18 is a simplified diagram of select components of one embodiment of a current sensor according to the disclosure.

FIG. 19 is a schematic of the current sensor of FIG. 18.

FIG. 20 is a sectional view of select components of still another embodiment of a current sensor according to the disclosure.

FIG. 21 is a sectional elevation view of select components of still another embodiment of a current sensor according to the disclosure.

FIG. 22 is a sectional plan view of the current sensor of FIG. 21.

The drawings are not necessarily to scale, or inclusive of all elements of a system, emphasis instead generally being placed upon illustrating the concepts, structures, and techniques sought to be protected herein.

### DETAILED DESCRIPTION

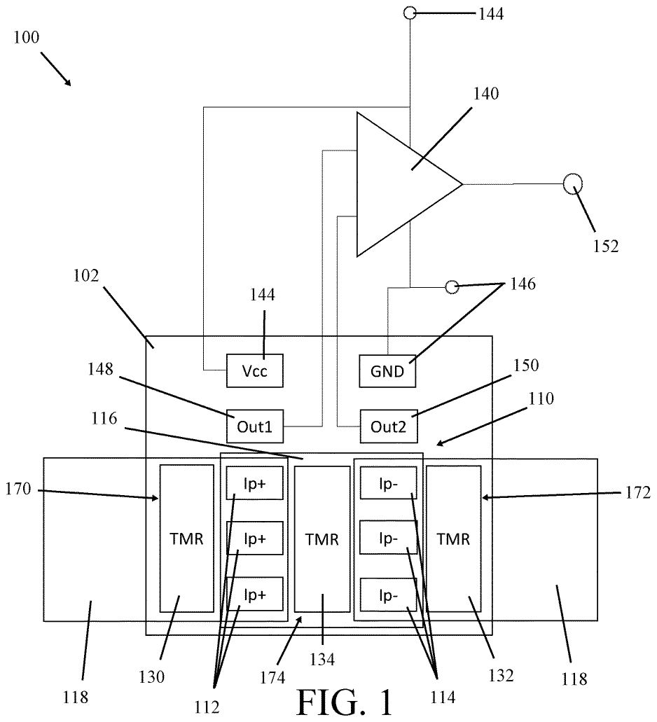

As shown in FIGS. 1, 2, and 3, a current sensor 100 according to the disclosure can be embodied in or on a current sensor die 102. The current sensor 100 can include a primary current path 110 to carry a primary current through the sensor 100 and a plurality of magnetic field sensors for sensing current flow along the primary current path 110. The primary current path 110 can include one or more inlet pillars 112 through which the primary current can enter the current sensor 100, one or more outlet pillars 114 through which the primary current can exit the current sensor 100, an internal conductor 116 coupled between the inlet and outlet pillars 112, 114, or any combination thereof. Any or all of the pillars 114, 116 can be coupled to one or more external conductors 118 through which the primary current flows, such as one or more field effect transistors, such as shown in FIG. 8, one or more bipolar junction transistors, one or more other transistors, one or more lead frames, such as shown in FIG. 9, one or more dies, one or more conductive traces, such as on a printed circuit boards (PCB), one or more busbars, one or more other external conductors, or any combination thereof. The primary current path 110, including the inlet pillars 112, the outlet pillars 114, the internal conductor 116, or any combination thereof can be designed, such as in terms of thickness, size, numerosity, material, other features, or any combination thereof, to minimize resistance to the primary current flowing through the current sensor 100, such as to minimize voltage drop across the current sensor 100 and/or heat transfer to the current sensor 100.

The current sensor 100 can include one or more magnetic field sensors 130 for sensing the primary current flowing through the inlet pillar 112, one or more magnetic field sensors 132 for sensing the primary current flowing through the outlet pillar 114, one or more magnetic field sensors 134 for sensing the primary current flowing through the internal conductor 116, or any combination thereof. For example, the magnetic field sensors can include a first magnetic field sensor 130 disposed adjacent the inlet pillar 112 and/or for sensing the primary current flowing through the inlet pillar 112, a second magnetic field sensor 132 disposed adjacent the outlet pillar 114 and/or for sensing the primary current flowing through the outlet pillar 114, and a third magnetic field sensor 134 disposed between the inlet pillar 112 and the outlet pillar 114 and/or for sensing the primary current flowing through the inlet pillar 112, the outlet pillar 114, the internal conductor 116, or any combination thereof.

In at least one embodiment, the current sensor 100 can include or be used with an amplifier 140, such as to amplify signals received from the magnetic field sensors 130, 132, 134 and/or to otherwise provide a signal indicative of the primary current. In some embodiments, the amplifier 140 can be on the die 102. In some embodiments, the amplifier 140 can be external to the die 102. The magnetic field sensors 130, 132, 134 can be electrically coupled in a bridge 142, such as a Wheatstone bridge as shown in FIG. 5 for example. The amplifier 140 can amplify signals received directly from the magnetic field sensors 130, 132, 134 and/or indirectly through the bridge 142. The current sensor 100 can include one or more pillars or other connections for the bridge 142, such as where the amplifier 140 is external to the die 102, or one or more pillars or other connections for the amplifier 140, such as where the amplifier 140 is onboard the die 102. For example, the current sensor 100 and/or the bridge 142 can include a supply connection 144, a ground connection 146, such as to supply power to the amplifier 140 and/or the bridge 142, a first output 148 of the bridge 142, such as to the amplifier 140, a second output 150 of the bridge 142, such as to the amplifier 140, a signal output 152 of the amplifier 140, or any combination thereof.

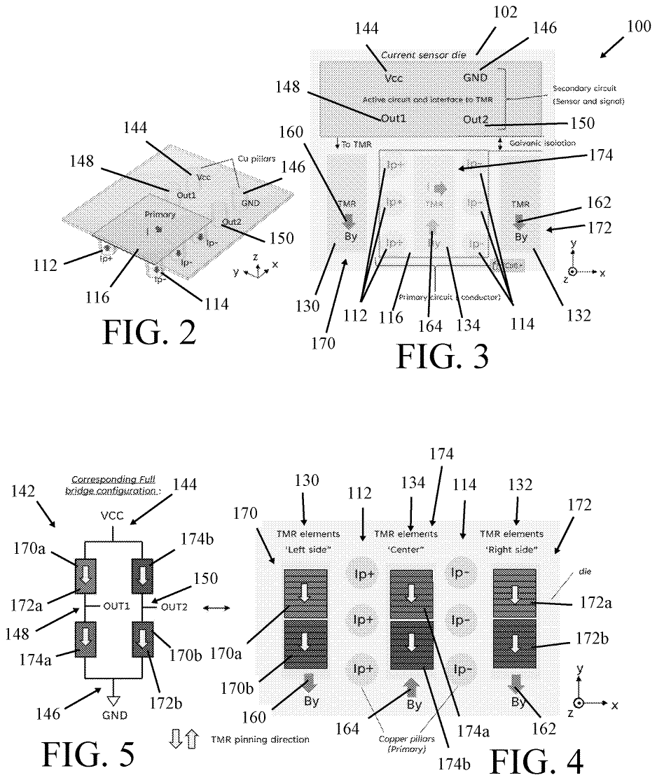

Any or all of the magnetic field sensors 130, 132, 134 can have parallel axes of sensitivity. For example, the first magnetic field sensor 130 can have a first axis of sensitivity 160 and the second magnetic field sensor 132 can have a second axis of sensitivity 162. The first axis of sensitivity 160 and the second axis of sensitivity 162 can be aligned parallel with one another and/or with the same polarity. Similarly, the third magnetic field sensor 134 can have a third axis of sensitivity 164, which can be aligned parallel to the first axis of sensitivity 160 and/or the second axis of sensitivity 162. In some embodiments, the third magnetic field sensor 134 and/or the third axis of sensitivity 164 can have an opposite or opposing polarity to the first magnetic field sensor 130, the first axis of sensitivity 160, the second magnetic field sensor 132, the second axis of sensitivity 162, or any combination thereof, such as shown in FIG. 3. For example, following the right-hand rule, one can visualize the magnetic fields surrounding the inlet pillars 112, the outlet pillar 114, and the internal conductor 116, shown in FIG. 2. Any or all of the magnetic field sensors 130 can be positioned and/or aligned to detect or sense those magnetic fields, and/or with appropriate polarities, to consistently detect or sense a magnitude and direction of the primary current flowing through the inlet pillars 112, the outlet pillar 114, the internal conductor 116, or any combination thereof.

As discussed above, the inlet pillar 112 can be or include a single inlet pillar 112 or a plurality of inlet pillars 112 and/or the outlet pillar 114 can be or include a single outlet pillar 114 or a plurality of outlet pillars 114. The plurality of inlet pillars 112 can be linearly aligned with one another and/or the plurality of outlet pillars 114 can be linearly aligned with one another, such as shown in FIGS. 1-3. The inlet pillars 114 can be aligned in parallel with the outlet pillars 114. The internal conductor 116 can include one or more conductors coupling the inlet pillars 112 and the outlet pillars 114. In some embodiments, the internal conductor 116 can be a single conductor, such as a planar conductor, coupling each of the inlet pillars 112 and the outlet pillars 114. For example, the internal conductor 116 can be a conductive layer, or portion thereof, in the die 102.

In some embodiments, the first magnetic field sensor 130 can be or include a single magnetic field sensing element 170 spanning the plurality of inlet pillars 112 and having an axis of sensitivity aligned parallel to the plurality of inlet pillars 112. The second magnetic field sensor 132 can be or include a single magnetic field sensing element 172 spanning the plurality of outlet pillars and having an axis of sensitivity aligned parallel to the plurality of outlet pillars. The third magnetic field sensor 174 can be or include a single magnetic field sensing element 134 spanning the plurality of inlet pillars 112 and/or the plurality of outlet pillars 114 and having an axis of sensitivity aligned parallel to the plurality of inlet pillars 112 and/or the plurality of outlet pillars 114.

In some embodiments, such as shown in FIG. 4, the first magnetic field sensor 130 can be or include a first magnetic field sensing element, or plurality of elements, 170a and a second magnetic field sensing element, or plurality of elements, 170b. The first magnetic field sensing element(s) 170a can span a portion of the plurality of inlet pillars 112 and/or the second magnetic field sensing element(s) 170b can span another portion of the plurality of inlet pillars 112. The first and second magnetic field sensing elements 170a, 170b, can be linearly aligned parallel to the plurality of inlet pillars 112 and/or can have an axis of sensitivity 160 aligned parallel to the plurality of inlet pillars 112.

In some embodiments, the second magnetic field sensor 132 can be or include a third magnetic field sensing element, or plurality of elements, 172a and a fourth magnetic field sensing element, or plurality of elements, 172b. The third magnetic field sensing element(s) 172a can span a portion of the plurality of outlet pillars 114 and/or the fourth magnetic field sensing element(s) 172b can span another portion of the plurality of outlet pillars 114. The third and fourth magnetic field sensing elements 172a, 172b can be linearly aligned parallel to the plurality of outlet pillars 114 and/or can have an axis of sensitivity 162 aligned parallel to the plurality of outlet pillars 114.

In some embodiments, the third magnetic field sensor 134 can be or include a fifth magnetic field sensing element, or plurality of elements, 174a and a sixth magnetic field sensing element, or plurality of elements, 174b. The fifth magnetic field sensing element(s) 174a can span portion of the plurality of inlet pillars 112 and/or outlet pillars 114. The sixth magnetic field sensing element(s) 174b can span another portion of the plurality of inlet pillars 112 and/or outlet pillars 114. The fifth and sixth magnetic field sensing elements 174a, 174b can be linearly aligned parallel to the plurality of inlet pillars 112 and/or outlet pillars 114. The fifth and sixth magnetic field sensing elements 174a, 174b can have an axis of sensitivity 164 aligned parallel to the plurality of inlet pillars 112 and/or the plurality of outlet pillars 114.

As shown in FIG. 5, any or all of the magnetic field sensing elements can be coupled in a bridge 142. For example, some of the magnetic field sensing elements 170 of the first magnetic field sensor 130, such as the first magnetic field sensing element(s) 170a, and/or some of the magnetic field sensing elements 172 of the second magnetic field sensor 132, such as the third magnetic field sensing element(s) 172a, can be coupled between the supply connection 144 and the first output 148 of the bridge 142. Some of the magnetic field sensing elements 174 of the third magnetic field sensor 134, such as the fifth magnetic field sensing element(s) 174a, can be coupled between the first output 148 and the ground connection 146 of the bridge 142. Some of the magnetic field sensing elements 174 of the third magnetic field sensor 134, such as sixth magnetic field sensing element(s) 174b, can be coupled between the supply connection 144 and the second output 150 of the bridge 142. Some of the magnetic field sensing elements 170 of the first magnetic field sensor 130, such as the second magnetic field sensing element(s) 170b, and/or some of the magnetic field sensing elements 172 of the second magnetic field sensor 132, such as the fourth magnetic field sensing element(s) 172b, can be coupled between the second output 150 and the ground connection 146 of the bridge 142. The amplifier 140 can amplify the signal at the first and second outputs 148, 150 of the bridge 142, such as to provide the signal output 152 of the amplifier 140.

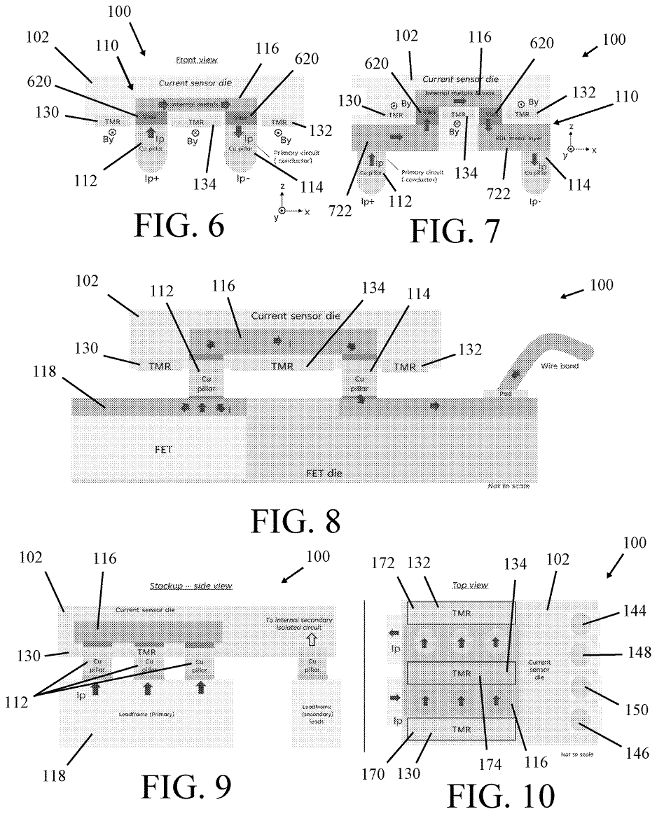

In at least one embodiment, as shown in FIG. 6 for example, the current sensor 100 and/or die 102 can be or include multiple layers. For example, the internal conductor 116 can be embedded within the die 102 and be coupled to the inlet and outlet pillars 112, 114 through one or more columns 620, such as one or more vertical interconnect access' (via) or one or more through-silicon vias (TSV), coupled between the inlet pillars 112, the outlet pillars 114, the internal conductor 116, or any combination thereof. The magnetic field sensors 130, 132, 134, and/or the magnetic field sensing elements 170, 172, 174, can be disposed surrounding the columns 620 for sensing the primary current flowing through the columns 620.

In some embodiments, the primary current path 110 can include a plurality of primary current paths 110 and the magnetic field sensors 130, 132, 134, and/or the magnetic field sensing elements 170, 172, 174 can be disposed surrounding any or all of the primary current paths 110. For example, the current sensor 100 can include a plurality of inlet pillars 112 and a plurality of outlet pillars 114, and the internal conductor 116 can be or include a single the internal conductor 116 coupling the inlet pillars 112 and the outlet pillars 114 or a plurality of internal conductors 116 coupling the inlet pillars 112 and the outlet pillars 114, such as in pairs. The columns 620 can couple the inlet pillars 112 and the outlet pillars 114 to the single the internal conductor 116, collectively, or the plurality of internal conductors 116, individually.

As shown in FIG. 7, the current sensor 100 or die 102 can include one or more redistribution layers 722 between the inlet pillars 112, the outlet pillars 114, the internal conductor(s) 116, the columns 620, or any combination thereof. In at least one embodiment, the primary current path 110 can include a first inlet pillar 112, a second inlet pillar 112, a first outlet pillar 114, a second outlet pillar 114, one or more inlet columns 620, one or more outlet columns 620, one or more internal conductor 116 electrically coupled between the inlet and outlet columns 620, one or more inlet redistribution layers 722 electrically coupled between the inlet pillars 112 and the inlet column(s) 620 or the internal conductor(s) 116, one or more outlet redistribution layers 722 electrically coupled between the outlet pillars 114 and the outlet column(s) 620 or the internal conductor(s) 116, or any combination thereof. The current sensor 100 can also include a first magnetic field sensor 130 for sensing the primary current flowing through the inlet column 620 and/or the inlet redistribution layer 722, a second magnetic field sensor 132 for sensing the primary current flowing through the outlet column 620 and/or the outlet redistribution layer 722, a third magnetic field sensor 134 disposed between the inlet column 620 and the outlet column 620 for sensing the primary current flowing through the columns 620 and/or the internal conductor 116, or any combination thereof.

As shown in FIG. 8, the current sensor 100 can be arranged as shown in FIGS. 2, 3, 4, 6, 7, or any combination thereof and be electrically coupled to a transistor, such as a field effect transistor, either directly or indirectly, such as through an external conductor 118. As shown in FIGS. 9 and 10, the current sensor 100 can be arranged as shown in FIGS. 2, 3, 4, 6, 7, or any combination thereof and be electrically coupled to lead frame or other external conductor(s) 118. The pillars or other connections for the bridge 142 and/or the amplifier 140 can be linearly aligned, such as shown in FIGS. 9 and 10, or otherwise arranged, such as shown in FIG. 2 and 3.

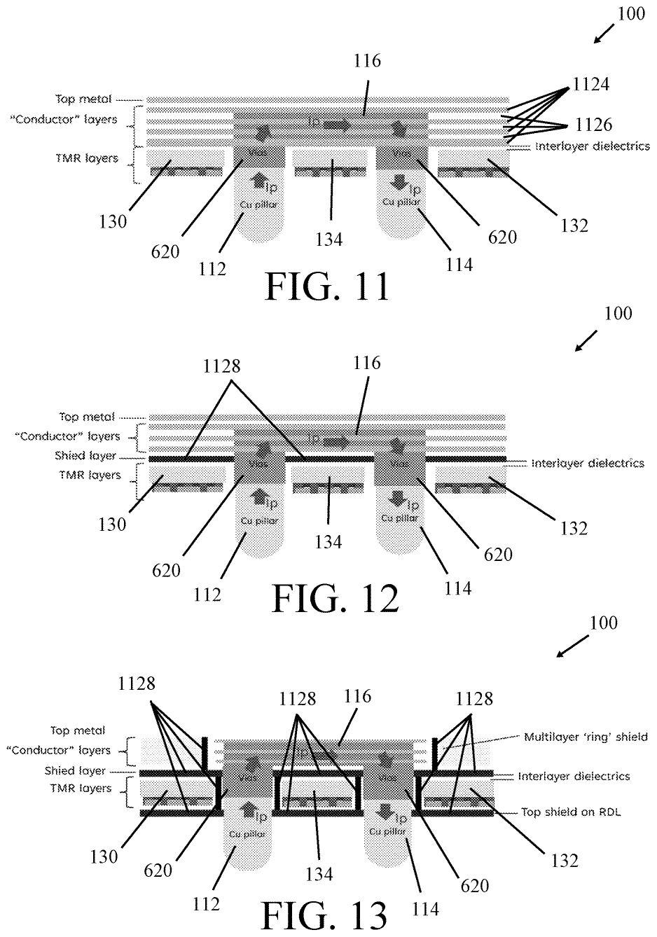

As shown in FIG. 11 for example, the internal conductor 116 and/or the redistribution layer(s) 722 can be or include one or more conductive layers 1124, which can be separated by dielectric layers 1126, of the die 102. The conductive layers 1124 can reduce an overall resistance of the internal conductor 116 and/or the redistribution layer(s) 722, extend beyond the internal conductor 116 and/or the redistribution layer(s) 722, extend around the internal conductor 116 and/or the redistribution layer(s) 722, or any combination thereof. In at least one embodiment, the current sensor 100 can include conductive layers 1124 for the internal conductor 116 and/or conductive layers 1124 for the redistribution layer(s) 722, which can be different. The current sensor 100 can include two or more conductive layers 1124 for the internal conductor 116 and/or two or more conductive layers 1124 for the redistribution layer(s) 722. In at least one embodiment, the current sensor 100 can include four conductive layers 1124 for the internal conductor 116 and/or one or more conductive layers 1124 for the redistribution layer(s) 722.

As shown in FIG. 12, one or more electric field shields 1228 can be disposed adjacent to the magnetic field sensors 130, 132, 134. The electric field shield 1228 can reduce external interference and/or other sources of error. For example, the electric field shield 1228 can reduce parasitic coupling (capacitive coupling) between the external conductor 118 and portions of the current sensor 100, such as the internal conductor 116, any or all of the magnetic field sensors 130, 132, 134, the amplifier 140, or any combination thereof. In at least one embodiment, the electric field shield 1228 can be disposed between the internal conductor 116 and any or all of the magnetic field sensors 130, 132, 134. The electric field shield 1228 can be electrically coupled to a fixed potential, such as the ground connection 146, and/or can reduce parasitic (capacitive) coupling.

As shown in FIG. 13, the electric field shields 1228 can be disposed between any or all of the magnetic field sensors 130, 132, 134 and any or all of the inlet pillars 112, the outlet pillars 114, the internal conductor 116, the columns 620, the redistribution layers 722, or any combination thereof. The electric field shield 1228 can be disposed above the magnetic field sensors 130, 132, 134, below the magnetic field sensors 130, 132, 134, surrounding any or all of the magnetic field sensors 130, 132, 134, surrounding any or all of the pillars 112, 114, surrounding the internal conductor 116, surrounding any or all of the columns 620, surrounding any or all of the redistribution layers 722, or any combination thereof. For example, a first electric field shield 1128 can be disposed between any or all of the magnetic field sensors 130, 132, 134 and the internal conductor 116 and a second electric field shield 1128 can be disposed on an opposing side of the magnetic field sensors 130, 132, 134 as the first electric field shield 1128.

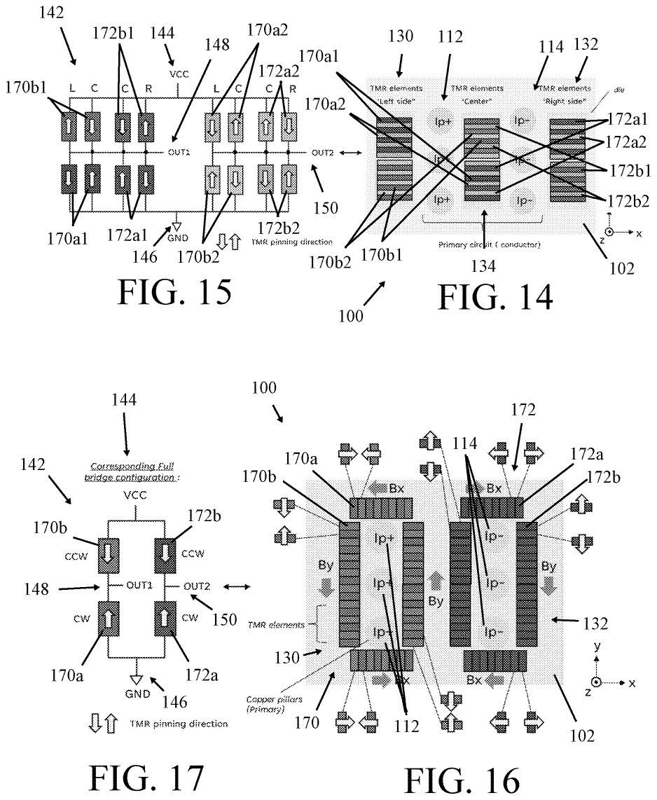

As shown in FIGS. 14, 15, 16, and 17, any or all of the magnetic field sensing elements 170, 172, 174 can be physically interlaced on the die 102 and electrically coupled in the bridge 142, either in series or parallel, with opposing or supporting polarities, or any combination thereof. For example, as shown in FIG. 14 for example, individual magnetic field sensing elements 170, 172, 174 can be grouped, such as in the groups or pluralities 170a, 170b, 172a, 172b, 174a, 174b discussed above. Those groups or pluralities can be further broken down with individual magnetic field sensing elements 170, 172, 174 from those groups physically disposed in different locations on the die 102 and electrically coupled into different groups in the bridge 142. For example, as shown in FIGS. 14 and 15, some of a first portion 170a1 of the magnetic field sensing elements 170a can be physically disposed to sense the primary current flowing through the inlet pillar(s) 112, such as part of the first magnetic field sensor 130, and some of that portion 170a1 can be physically disposed to sense the primary current flowing through the pillars 112, 114 and/or the internal conductor 116, such as part of the third magnetic field sensor 134, and any or all of that portion 170a1 of the magnetic field sensing elements 170 a can be electrically coupled between the first output 148 and the ground connection 146 of the bridge 142, with opposing and/or supporting polarities. Some of a second portion 170a2 of the magnetic field sensing elements 170a can be physically disposed to sense the primary current flowing through the inlet pillar(s) 112, such as part of the first magnetic field sensor 130, and some of that portion 170a2 can be physically disposed to sense the primary current flowing through the pillars 112, 114 and/or the internal conductor 116, such as part of the third magnetic field sensor 134, and any or all of that portion 170a2 of the magnetic field sensing elements 170a can be electrically coupled between the supply connection 144 and the second output 150 of the bridge 142, with opposing and/or supporting polarities. Some of a first portion 170b1 of the magnetic field sensing elements 170b can be physically disposed to sense the primary current flowing through the inlet pillar(s) 112, such as part of the first magnetic field sensor 130, and some of that portion 170b1 can be physically disposed to sense the primary current flowing through the pillars 112, 114 and/or the internal conductor 116, such as part of the third magnetic field sensor 134, and any or all of that portion 170b1 of the magnetic field sensing elements 170b can be electrically coupled between the supply connection 144 and the first output 148 of the bridge 142, with opposing and/or supporting polarities. Some of a second portion 170b2 of the magnetic field sensing elements 170b can be physically disposed to sense the primary current flowing through the inlet pillar(s) 112, such as part of the first magnetic field sensor 130, and some of that portion 170b2 can be physically disposed to sense the primary current flowing through the pillars 112, 114 and/or the internal conductor 116, such as part of the third magnetic field sensor 134, and any or all of that portion 170b2 of the magnetic field sensing elements 170b can be electrically coupled between the second output 150 and the ground connection 146 of the bridge 142, with opposing and/or supporting polarities.

Similarly, as shown in FIGS. 14 and 15 for example, some of a first portion 172a1 of the magnetic field sensing elements 172a can be physically disposed to sense the primary current flowing through the outlet pillar(s) 114, such as part of the second magnetic field sensor 132, and some of that portion 172a1 can be physically disposed to sense the primary current flowing through the pillars 112, 114 and/or the internal conductor 116, such as part of the third magnetic field sensor 134, and any or all of that portion 172a1 of the magnetic field sensing elements 172a can be electrically coupled between the first output 148 and the ground connection 146 of the bridge 142, with opposing and/or supporting polarities. Some of a second portion 172a2 of the magnetic field sensing elements 172a can be physically disposed to sense the primary current flowing through the outlet pillar(s) 114, such as part of the second magnetic field sensor 132, and some of that portion 172a2 can be physically disposed to sense the primary current flowing through the pillars 112, 114 and/or the internal conductor 116, such as part of the third magnetic field sensor 134, and any or all of that portion 172a2 of the magnetic field sensing elements 170a can be electrically coupled between the supply connection 144 and the second output 150 of the bridge 142, with opposing and/or supporting polarities. Some of a first portion 172b1 of the magnetic field sensing elements 172b can be physically disposed to sense the primary current flowing through the outlet pillar(s) 114, such as part of the second magnetic field sensor 132, and some of that portion 172b1 can be physically disposed to sense the primary current flowing through the pillars 112, 114 and/or the internal conductor 116, such as part of the third magnetic field sensor 134, and any or all of that portion 172b1 of the magnetic field sensing elements 172b can be electrically coupled between the supply connection 144 and the first output 148 of the bridge 142, with opposing and/or supporting polarities. Some of a second portion 172b2 of the magnetic field sensing elements 172b can be physically disposed to sense the primary current flowing through the outlet pillar(s) 114, such as part of the second magnetic field sensor 132, and some of that portion 172b2 can be physically disposed to sense the primary current flowing through the pillars 112, 114 and/or the internal conductor 116, such as part of the third magnetic field sensor 134, and any or all of that portion 172b2 of the magnetic field sensing elements 172b can be electrically coupled between the second output 150 and the ground connection 146 of the bridge 142, with opposing and/or supporting polarities.

In at least one embodiment, any or all of the primary current paths 110, or portions thereof, such as the pillars 112, 114 and/or the columns 620 can be aligned in parallel with a Z-axis, and any or all of the magnetic field sensors 130, 132, 134, or the magnetic field sensing elements 170, 172, 174, can be aligned with their axis of sensitivity 160, 162, 164, orthogonal to the Z-axis. For example, some of the magnetic field sensors 130, 132, 134, or the magnetic field sensing elements 170, 172, 174 can be aligned with their axis of sensitivity parallel to an X-axis, and some of the magnetic field sensors 130, 132, 134, or the magnetic field sensing elements 170, 172, 174 can be aligned with their axis of sensitivity parallel to a Y-axis. The X-axis can be orthogonal to the Z-axis and/or the Y-axis, which can be orthogonal to the Z-axis.

For example, any or all of the inlet pillars 112 and/or outlet pillars 114 can be aligned in parallel with a Z-axis. Some of the magnetic field sensing elements 170a can be aligned with their axis of sensitivity 160 parallel to an X-axis and/or some of the magnetic field sensing elements 170a can be aligned with their axis of sensitivity 160 parallel to a Y-axis. Some of the magnetic field sensing elements 170b can be aligned with their axis of sensitivity 160 parallel to an X-axis and/or some of the magnetic field sensing elements 170b can be aligned with their axis of sensitivity 160 parallel to a Y-axis. Some of the magnetic field sensing elements 172a can be aligned with their axis of sensitivity 162 parallel to an X-axis and/or some of the magnetic field sensing elements 172a can be aligned with their axis of sensitivity 162 parallel to a Y-axis. Some of the magnetic field sensing elements 177b can be aligned with their axis of sensitivity 162 parallel to an X-axis and/or some of the magnetic field sensing elements 172b can be aligned with their axis of sensitivity 162 parallel to a Y-axis. The X-axis can be orthogonal to the Z-axis and/or the Y-axis, which can be orthogonal to the Z-axis. The axes of sensitivity 160, 162, and/or the polarities thereof, can be arranged according to the right-hand rule with respect to the primary current flowing through the inlet pillars 112 and the outlet pillars 114.

In some embodiments, the third magnetic field sensor 134 can be divided into multiple groups similarly to the first and second magnetic field sensors 130, 132. For example, the third magnetic field sensor 134 be or include the third plurality of magnetic field sensing elements 174, which can be divided or grouped into a first group, portion, or plurality of magnetic field sensing elements 174a and a second group, portion, or plurality of magnetic field sensing elements 174b. In at least some embodiments, the first plurality of magnetic field sensing elements 174a can span some of the inlet pillar(s) 112 and/or outlet pillar(s) 114 and the second plurality of magnetic field sensing elements 174b can span others of the inlet pillar(s) 112 and/or outlet pillar(s) 114, such as shown in FIG. 4. For example, the first plurality of magnetic field sensing elements 174a can be laterally spaced apart from the second plurality of magnetic field sensing elements 174b, such as along the Y-axis. In at least some embodiments, the first plurality of magnetic field sensing elements 174a can span the inlet pillar(s) 112 and the second plurality of magnetic field sensing elements 174b can span the outlet pillar(s) 114. For example, the first plurality of magnetic field sensing elements 174a can be laterally spaced apart from the second plurality of magnetic field sensing elements 174b, such as along the X-axis. Any or all of the third plurality of magnetic field sensing elements 174 can have an axis of sensitivity aligned parallel to the inlet pillars 112 and/or outlet pillars 114.

As shown in FIGS. 16 and 17 for example, the first magnetic field sensor 130, and/or the first magnetic field sensing elements 170, can completely or partially surround the inlet pillar(s) 112 and/or the second magnetic field sensor 132, and/or the second magnetic field sensing elements 172, can completely or partially surround the outlet pillar(s) 114. For example, in some embodiments, the magnetic field sensing elements 170a and the magnetic field sensing elements 170b can be physically disposed around the inlet pillar(s) 112, such as in an alternating pattern and/or have opposing polarities. The magnetic field sensing elements 170a can be electrically coupled between the first output 148 and the ground connection 146 of the bridge 142 and/or the magnetic field sensing elements 170b can be electrically coupled between the supply connection 144 and the first output 148 of the bridge 142. In some embodiments, the magnetic field sensing elements 172a and the magnetic field sensing elements 172b can be physically disposed around the outlet pillar(s) 114, such as in an alternating pattern and/or have opposing polarities. The magnetic field sensing elements 172a can be electrically coupled between the second output 150 and the ground connection 146 of the bridge 142 and/or the magnetic field sensing elements 172b can be electrically coupled between the supply connection 144 and the second output 150 of the bridge 142.

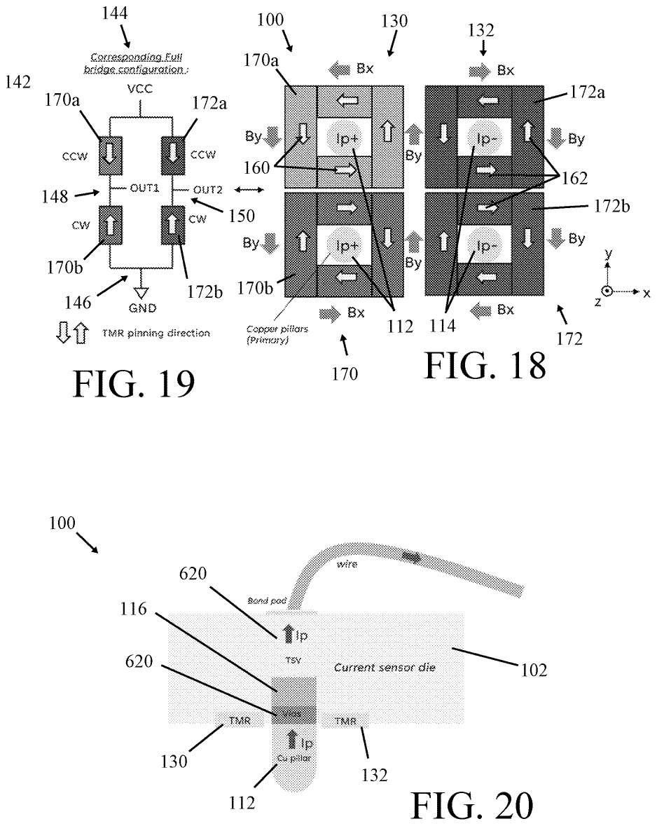

Similarly, as shown in FIGS. 18 and 19 for example, the first magnetic field sensor 130, and/or the first magnetic field sensing elements 170, can completely or partially surround individual ones of the inlet pillar(s) 112 and/or the second magnetic field sensor 132, and/or the second magnetic field sensing elements 172, can completely or partially surround individual ones of the outlet pillar(s) 114. In some embodiments, a first plurality of magnetic field sensing elements 170a can be physically disposed to completely or partially surround one of the inlet pillar(s) 112 and/or be electrically coupled between the supply connection 144 and the first output 148 of the bridge 142 while a second plurality of magnetic field sensing elements 170b can be physically disposed to completely or partially surround another of the inlet pillar(s) 112 and/or be electrically coupled between the first output 148 and the ground connection 146 of the bridge 142. In some embodiments, a first plurality of magnetic field sensing elements 172a can be physically disposed to completely or partially surround one of the outlet pillar(s) 114 and/or be electrically coupled between the supply connection 144 and the second output 150 of the bridge 142 while a second plurality of magnetic field sensing elements 172b can be physically disposed to completely or partially surround another of the outlet pillar(s) 114 and/or be electrically coupled between the second output 150 and the ground connection 146 of the bridge 142. In the bridge, the polarities of the individual magnetic field sensing elements 170, 172 can be opposing, as shown in FIGS. 16, 17, 18 and 19, or supporting, as shown in FIGS. 4 and 5.

As shown in FIG. 20, the primary current can flow through the die 102 of the current sensor 100. One or more inlet pillars 112 can extend from one side of the die 102. The primary current can flow into one or more inlet pillars 112, through one or more internal conductors 116 and/or one or more columns 620, such as one or more vias and/or TSVs, and exit the die 102 on an opposite side of the die 102. A first magnetic field sensor 130 and/or a second magnetic field sensor 132 can be disposed around the inlet pillars 112, the internal conductors 116, the columns 620, or any combination thereof and sense the primary current flowing therethrough.

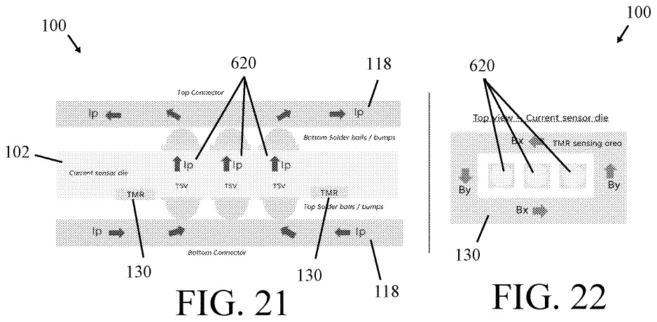

As shown in FIGS. 21 and 22, the current sensor 100 can be disposed between two external conductors 118. The primary current can flow into one side of the die 102, through one or more columns 620, such as one or more vias and/or TSVs, and exit the die 102 on an opposite side of the die 102. A magnetic field sensor 130 can be disposed around the columns 620 and sense the primary current flowing therethrough.

A current sensor 100 according to the disclosure can include a primary current path 110 to carry a primary current, which can include a plurality of linearly aligned inlet pillars 112, a plurality of linearly aligned outlet pillars 114, an internal conductor 116 coupled between the inlet pillars 112 and the outlet pillar 114, or any combination thereof. The inlet pillars 112 and the outlet pillars 114 can be aligned in parallel. The current sensor 100 can also include a first magnetic field sensor 130 for sensing the primary current flowing through the inlet pillars 112, a second magnetic field sensor 132 for sensing the primary current flowing through the outlet pillars 114, a third magnetic field sensor 134 disposed between the inlet pillars 112 and the outlet pillars 114 for sensing the primary current flowing through the inlet pillars 112, the outlet pillars 114, the internal conductor, or any combination thereof. The first magnetic field sensor 130 can have a first axis of sensitivity 160 aligned parallel to the inlet pillars 112, the second magnetic field sensor 132 can have a second axis of sensitivity 162 aligned parallel to the outlet pillars 114, the third magnetic field sensor 134 can have a third axis of sensitivity 164 that is aligned parallel to the first axis of sensitivity 160 and/or the second axis of sensitivity 162. Any or all of the axis of sensitivity 160, 162, 164 can have opposing and/or supporting polarities.

The first magnetic field sensor 130 can be or include a single magnetic field sensing element 170 spanning the inlet pillars 112, a plurality of magnetic field sensing elements 170 that, together, can span the plurality of inlet pillars 112, multiple groups or pluralities of magnetic field sensing elements 170a, 170b that, together, can span the plurality of inlet pillars 112, or any combination thereof. Any or all of the magnetic field sensing elements 170, 170a, 170b can be linearly aligned parallel to the inlet pillars 112. The pluralities of magnetic field sensing elements 170a, 170b can be spaced from each other, such as along the X-axis and/or the Y-axis.

The second magnetic field sensor 132 can be or include a single magnetic field sensing element 172 spanning the outlet pillars 114, a plurality of magnetic field sensing elements 172 that, together, can span the plurality of outlet pillars 114, multiple groups or pluralities of magnetic field sensing elements 172a, 172b that, together, can span the plurality of outlet pillars 114, or any combination thereof. Any or all of the magnetic field sensing elements 172 can be linearly aligned parallel to the outlet pillars 114. The pluralities of magnetic field sensing elements 172a, 172b can be spaced from each other, such as along the X-axis and/or the Y-axis.

The third magnetic field sensor 134 can be or include a single magnetic field sensing element 174 spanning the inlet pillars 112 and/or the outlet pillars 114, a plurality of magnetic field sensing elements 174 that, together, can span the plurality of inlet pillars 112 and/or outlet pillars 114, multiple groups or pluralities of magnetic field sensing elements 174a, 174b that, together, can span the plurality of inlet pillars 112 and/or outlet pillars 114, multiple groups or pluralities of magnetic field sensing elements 174a, 174b that, each, can span the plurality of inlet pillars 112 and/or outlet pillars 114, or any combination thereof. Any or all of the magnetic field sensing elements 174, 174a, 174b can be linearly aligned parallel to the inlet pillars 112 and/or outlet pillars 114. The pluralities of magnetic field sensing elements 174a, 174b can be spaced from each other, such as along the X-axis and/or the Y-axis.

As used in the claims or elsewhere herein, the term “comprising” does not exclude other elements or steps, and the indefinite article “a” or “an” does not exclude a plurality. As used herein, the term “magnetic field sensing element” is used to describe a variety of electronic elements that can sense a magnetic field. The magnetic field sensing elements 170, 172, 174 can be, but is not limited to, a Hall effect element, a magnetoresistance element, or a magnetotransistor. As is known, there are different types of Hall effect elements, for example, a planar Hall element, and a vertical Hall element. As is also known, there are different types of magnetoresistance elements, for example, a semiconductor magnetoresistance element such as Indium Antimonide (InSb), a giant magnetoresistance (GMR) element, for example, a spin valve, an anisotropic magnetoresistance element (AMR), a tunneling magnetoresistance (TMR) element, and a magnetic tunnel junction (MTJ). The magnetic field sensing element may be a single element or, alternatively, may include two or more magnetic field sensing elements arranged in various configurations, e.g., a half bridge or full (Wheatstone) bridge. Depending on the device type and other application requirements, the magnetic field sensing element may be a device made of a type IV semiconductor material such as Silicon (Si) or Germanium (Ge), or a type III-V semiconductor material like Gallium-Arsenide (GaAs) or an Indium compound, e.g., Indium-Antimonide (InSb).

As is known, some of the above-described magnetic field sensing elements tend to have an axis of maximum sensitivity parallel to a substrate that supports the magnetic field sensing element, and others of the above-described magnetic field sensing elements tend to have an axis of maximum sensitivity perpendicular to a substrate that supports the magnetic field sensing element. In particular, planar Hall elements tend to have axes of sensitivity perpendicular to a substrate, while metal based or metallic magnetoresistance elements (e.g., GMR, TMR, AMR) and vertical Hall elements tend to have axes of sensitivity parallel to a substrate.

While electronic circuits shown in figures herein may be shown in the form of analog blocks or digital blocks, it will be understood that the analog blocks can be replaced by digital blocks that perform the same or similar functions and the digital blocks can be replaced by analog blocks that perform the same or similar functions. Analog-to-digital or digital-to-analog conversions may not be explicitly shown in the figures but should be understood.

Various embodiments of the concepts systems and techniques are described herein with reference to the related drawings. Alternative embodiments can be devised without departing from the scope of the described concepts. It is noted that various connections and positional relationships (e.g., over, below, adjacent, etc.) are set forth between elements in the claims, detailed description, and drawings. These connections and/or positional relationships, unless specified otherwise, can be direct or indirect, and the claimed inventions are not intended to be limiting in this respect. Accordingly, a coupling/connection of entities can refer to either a direct or an indirect coupling/connection, and a positional relationship between entities can be a direct or indirect positional relationship. As an example of an indirect positional relationship, references in the present description to element or structure A coupled/connected to element or structure B include situations in which one or more intermediate elements or structures (e.g., element C) is provided between elements A and B regardless of whether the characteristics and functionalities of elements A and/or B are substantially changed by the intermediate element(s).

Furthermore, it should be appreciated that relative, directional or reference terms (e.g. such as “above,” “below,” “left,” “right,” “top,” “bottom,” “vertical,” “horizontal,” “front,” “back,” “rearward,” “forward,” etc.) and derivatives thereof are used only to promote clarity in the description of the figures. Such terms are not intended as, and should not be construed as, limiting. Such terms may simply be used to facilitate discussion of the drawings and may be used, where applicable, to promote clarity of description when dealing with relative relationships, particularly with respect to the illustrated embodiments. Such terms are not, however, intended to imply absolute relationships, positions, and/or orientations. For example, with respect to an object or structure, an “upper” or “top” surface can become a “lower” or “bottom” surface simply by turning the object over. Nevertheless, it is still the same surface and the object remains the same.

The terms “disposed over,” “overlying,” “atop,” “on top,” “positioned on” or “positioned atop” mean that a first element, such as a first structure, is present on a second element, such as a second structure, where intervening elements or structures (such as an interface structure) may or may not be present between the first element and the second element. The term “direct contact” means that a first element, such as a first structure, and a second element, such as a second structure, are connected without any intermediary elements or structures between the interface of the two elements. The term “connection” can include an indirect connection and a direct connection.

In the foregoing detailed description, various features are grouped together in one or more individual embodiments for the purpose of streamlining the disclosure. This method of disclosure is not to be interpreted as reflecting an intention that each claim requires more features than are expressly recited therein. Rather, inventive aspects may lie in less than all features of each disclosed embodiment.

References in the disclosure to “one embodiment,” “an embodiment,” “some embodiments,” or variants of such phrases indicate that the embodiment(s) described can include a particular feature, structure, or characteristic, but every embodiment can include the particular feature, structure, or characteristic. Moreover, such phrases are not necessarily referring to the same embodiment(s). Further, when a particular feature, structure, or characteristic is described in connection knowledge of one skilled in the art to affect such feature, structure, or characteristic in connection with other embodiments whether or not explicitly described.

Use of ordinal terms such as “first,” “second,” “third,” etc., in the claims to modify a claim element does not by itself connote any priority, precedence, or order of one claim element over another or the temporal order in which acts of a method are performed, but are used merely as labels to distinguish one claim element having a certain name from another element having a same name (but for use of the ordinal term) to distinguish the claim elements.

The disclosed subject matter is not limited in its application to the details of construction and to the arrangements of the components set forth in the detailed description or illustrated in the drawings. The disclosed subject matter is capable of other embodiments and of being practiced and carried out in various ways. As such, those skilled in the art will appreciate that the conception, upon which this disclosure is based, may readily be utilized as a basis for the designing of other structures, methods, and systems for carrying out the several purposes of the disclosed subject matter. Therefore, the claims should be regarded as including such equivalent constructions insofar as they do not depart from the spirit and scope of the disclosed subject matter.

Although the disclosed subject matter has been described and illustrated in the foregoing exemplary embodiments, it is understood that the present disclosure has been made only by way of example, and that numerous changes in the details of implementation of the disclosed subject matter may be made without departing from the spirit and scope of the disclosed subject matter.

Other variations to the disclosed embodiments can be understood and effected by those skilled in the art in practicing the claimed invention, from a study of the drawings, the disclosure, and the appended claims.

The mere fact that certain measures are recited in mutually different dependent claims does not indicate that a combination of these measures cannot be used to obtain an advantage.

Any reference signs in the claims should not be construed as limiting the scope.

All publications and references cited herein are expressly incorporated herein by reference in their entirety.

What is claimed is:

1. A current sensor comprising:
a primary current path to carry a primary current, comprising
an inlet pillar;
an outlet pillar; and
an internal conductor coupled between the inlet and outlet pillars;
a first magnetic field sensor configured to sense the primary current flowing through the inlet pillar;
a second magnetic field sensor configured to sense the primary current flowing through the outlet pillar; and
a third magnetic field sensor disposed between the inlet pillar and the outlet pillar and configured to sense the primary current flowing through the internal conductor.

2. The current sensor of claim 1, wherein the third magnetic field sensor is further configured to sense the primary current flowing through the inlet pillar.

3. The current sensor of claim 1, wherein the third magnetic field sensor is further configured to sense the primary current flowing through the outlet pillar.

4. The current sensor of claim 1, wherein the third magnetic field sensor is further configured to sense the primary current flowing through the inlet pillar and the outlet pillar.

5. The current sensor of claim 1, wherein the first magnetic field sensor has a first axis of sensitivity; wherein the second magnetic field sensor has a second axis of sensitivity; and wherein the first axis of sensitivity and the second axis of sensitivity are aligned parallel with one another.

6. The current sensor of claim 5, wherein the third magnetic field sensor has a third axis of sensitivity that is aligned parallel to the first axis of sensitivity and the second axis of sensitivity.

7. The current sensor of claim 1, wherein the inlet pillar comprises a plurality of linearly aligned inlet pillars; wherein the outlet pillar comprises a plurality of linearly aligned outlet pillars; and wherein the inlet pillars are aligned in parallel with the outlet pillars.

8. The current sensor of claim 7, wherein the internal conductor comprises a single conductor coupling the inlet pillars and the outlet pillars.

9. The current sensor of claim 7, wherein the first magnetic field sensor comprises a single magnetic field sensing element spanning the plurality of inlet pillars and having an axis of sensitivity aligned parallel to the plurality of inlet pillars.

10. The current sensor of claim 7, wherein the second magnetic field sensor comprises a single magnetic field sensing element spanning the plurality of outlet pillars and having an axis of sensitivity aligned parallel to the plurality of outlet pillars.

11. The current sensor of claim 7, wherein the third magnetic field sensor comprises a single magnetic field sensing element spanning the plurality of inlet pillars and having an axis of sensitivity aligned parallel to the plurality of inlet pillars.

12. The current sensor of claim 7, wherein the first magnetic field sensor comprises a plurality of magnetic field sensing elements; wherein the plurality of magnetic field sensing elements spans the plurality of inlet pillars; wherein the plurality of magnetic field sensing elements is linearly aligned parallel to the plurality of inlet pillars; and wherein each magnetic field sensing element has an axis of sensitivity aligned parallel to the plurality of inlet pillars.

13. The current sensor of claim 7, wherein the second magnetic field sensor comprises a plurality of magnetic field sensing elements; wherein the plurality of magnetic field sensing elements spans the plurality of outlet pillars; wherein the plurality of magnetic field sensing elements is linearly aligned parallel to the plurality of outlet pillars; and wherein each magnetic field sensing element has an axis of sensitivity aligned parallel to the plurality of outlet pillars.

14. The current sensor of claim 7, wherein the third magnetic field sensor comprises a first plurality of magnetic field sensing elements; wherein the first plurality of magnetic field sensing elements spans the plurality of inlet pillars; wherein the first plurality of magnetic field sensing elements is linearly aligned parallel to the plurality of inlet pillars; and wherein each magnetic field sensing element has an axis of sensitivity aligned parallel to the plurality of inlet pillars.

15. The current sensor of claim 14, wherein the third magnetic field sensor further comprises a second plurality of magnetic field sensing elements; wherein the second plurality of magnetic field sensing elements spans the plurality of outlet pillars; and wherein the second plurality of magnetic field sensing elements is linearly aligned parallel to the plurality of outlet pillars.

16. The current sensor of claim 15, wherein the first plurality of magnetic field sensing elements is laterally spaced apart from the second plurality of magnetic field sensing elements.

17. The current sensor of claim 7, wherein the first magnetic field sensor comprises a first magnetic field sensing element and a second magnetic field sensing element; wherein the first magnetic field sensing element spans a first portion of the plurality of inlet pillars; wherein the second magnetic field sensing element spans a second portion of the plurality of inlet pillars; wherein the first and second magnetic field sensing elements are linearly aligned parallel to the plurality of inlet pillars; and wherein each magnetic field sensing element has an axis of sensitivity aligned parallel to the plurality of inlet pillars.

18. The current sensor of claim 17, wherein the second magnetic field sensor comprises a third magnetic field sensing element and a fourth magnetic field sensing element; wherein the third magnetic field sensing element spans a third portion of the plurality of outlet pillars; wherein the fourth magnetic field sensing element spans a fourth portion of the plurality of outlet pillars; and wherein the third and fourth magnetic field sensing elements are linearly aligned parallel to the plurality of outlet pillars.

19. The current sensor of claim 18, wherein the third magnetic field sensor comprises a fifth magnetic field sensing element and a sixth magnetic field sensing element; wherein the fifth magnetic field sensing element spans the first portion of the plurality of inlet pillars; wherein the sixth magnetic field sensing element spans the second portion of the plurality of inlet pillars; wherein the fifth and sixth magnetic field sensing elements are linearly aligned parallel to the plurality of inlet pillars; and wherein the magnetic field sensing elements are coupled in a bridge.

20. The current sensor of claim 19, wherein the first magnetic field sensing element and the third magnetic field sensing element are coupled between a supply connection and a first output of the bridge; wherein the sixth magnetic field sensing element is coupled between the supply connection and a second output of the bridge; wherein the fifth magnetic field sensing element is coupled between the first output and a ground connection; and wherein the second magnetic field sensing element and the fourth magnetic field sensing element are coupled between the second output and the ground connection.

21. The current sensor of claim 7, wherein the first magnetic field sensor comprises a first plurality of magnetic field sensing elements and a second plurality of magnetic field sensing elements; wherein the first plurality of magnetic field sensing elements spans a first portion of the plurality of inlet pillars; wherein the second plurality of magnetic field sensing elements spans a second portion of the plurality of inlet pillars; wherein the first plurality of magnetic field sensing elements and the second plurality of magnetic field sensing elements are linearly aligned parallel to the plurality of inlet pillars; and wherein each magnetic field sensing element has an axis of sensitivity aligned parallel to the plurality of inlet pillars.

22. The current sensor of claim 21, wherein the second magnetic field sensor comprises a third plurality of magnetic field sensing elements and a fourth plurality of magnetic field sensing elements; wherein the third plurality of magnetic field sensing elements spans a third portion of the plurality of outlet pillars; wherein the fourth plurality of magnetic field sensing elements spans a fourth portion of the plurality of outlet pillars; and wherein the third plurality of magnetic field sensing elements and the fourth plurality of magnetic field sensing elements are linearly aligned parallel to the plurality of outlet pillars.

23. The current sensor of claim 22, wherein the third magnetic field sensor comprises a fifth plurality of magnetic field sensing elements and a sixth plurality of magnetic field sensing elements; wherein the fifth plurality of magnetic field sensing elements spans the first portion of the plurality of inlet pillars; wherein the sixth plurality of magnetic field sensing elements spans the second portion of the plurality of inlet pillars; wherein the fifth plurality of magnetic field sensing elements and sixth plurality of magnetic field sensing elements are linearly aligned parallel to the plurality of inlet pillars; and wherein the magnetic field sensing elements are coupled in a bridge.

24. The current sensor of claim 23, wherein the first plurality of magnetic field sensing elements and the third plurality of magnetic field sensing elements are coupled between a supply connection and a first output of the bridge; wherein the sixth plurality of magnetic field sensing elements is coupled between the supply connection and a second output of the bridge; wherein the fifth plurality of magnetic field sensing elements is coupled between the first output and a ground connection; and wherein the second plurality of magnetic field sensing elements and the fourth plurality of magnetic field sensing elements are coupled between the second output and the ground connection.

25. The current sensor system of claim 1, further comprising a first electric field shield disposed between the magnetic field sensors and the internal conductor.

26. The current sensor system of claim 25, further comprising a second electric field shield disposed on an opposing side of the magnetic field sensors as the first electric field shield.

27. The current sensor system of claim 1, further comprising an electric field shield surrounding each of the magnetic field sensors.

28. The current sensor system of claim 1, further comprising an electric field shield surrounding the pillars.

29. The current sensor system of claim 1, wherein the inlet pillar is configured to be coupled to a field effect transistor.

30. The current sensor system of claim 1, wherein the inlet pillar is configured to be coupled to a lead frame.

31. A current sensor system comprising:
a primary current path to carry a primary current, comprising
a first inlet pillar;
a second inlet pillar;
a first outlet pillar;
a second outlet pillar; and
an internal conductor coupled between the inlet and outlet pillars;
a first plurality of magnetic field sensing elements disposed surrounding the first inlet pillar and configured to sense the primary current flowing through the first inlet pillar;
a second plurality of magnetic field sensing elements disposed surrounding the second inlet pillar and configured to sense the primary current flowing through the second inlet pillar;
a third plurality of magnetic field sensing elements disposed surrounding the first outlet pillar and configured to sense the primary current flowing through the first outlet pillar; and
a fourth plurality of magnetic field sensing elements disposed surrounding the second outlet pillar and configured to sense the primary current flowing through the second outlet inlet pillar.

32. The current sensor system of claim 31, wherein the magnetic field sensing elements are electrically coupled in a bridge.

33. The current sensor system of claim 32, wherein the first plurality of magnetic field sensing elements are coupled between a supply connection and a first output of the bridge; wherein the second plurality of magnetic field sensing elements are coupled between the first output and a ground connection of the bridge; wherein the third plurality of magnetic field sensing elements are coupled between the supply connection and a second output of the bridge; and wherein the fourth plurality of magnetic field sensing elements are coupled between the second output and the ground connection.

34. The current sensor system of claim 31, wherein the first inlet pillar is aligned in parallel with a Z-axis; wherein some of the first plurality of magnetic field sensing elements are aligned with their axis of sensitivity parallel to an X-axis, which is orthogonal to the Z-axis; and wherein some of the first plurality of magnetic field sensing elements are aligned with their axis of sensitivity parallel to a Y-axis, which is orthogonal to both the X-axis and the Z-axis.

35. The current sensor system of claim 31, wherein the first outlet pillar is aligned in parallel with a Z-axis; wherein some of the third plurality of magnetic field sensing elements are aligned with their axis of sensitivity parallel to an X-axis, which is orthogonal to the Z-axis; and wherein some of the third plurality of magnetic field sensing elements are aligned with their axis of sensitivity parallel to a Y-axis, which is orthogonal to both the X-axis and the Z-axis.

36. The current sensor system of claim 31, wherein the inlet and outlet pillars aligned in parallel with a Z-axis; wherein some of each plurality of magnetic field sensing elements are aligned with their axis of sensitivity parallel to an X-axis, which is orthogonal to the Z-axis; and wherein some of each plurality of magnetic field sensing elements are aligned with their axis of sensitivity parallel to a Y-axis, which is orthogonal to both the X-axis and the Z-axis.

37. A current sensor system comprising:
a primary current path to carry a primary current, comprising
an inlet pillar;
an outlet pillar; and
a through-silicon via (TSV) coupled between the inlet and outlet pillars; and
a plurality of magnetic field sensing elements disposed surrounding the TSV and configured to sense the primary current flowing through the TSV.

38. The current sensor system of claim 37, wherein the primary current path comprises a plurality of primary current paths; and wherein the plurality of magnetic field sensing elements is disposed surrounding the plurality of primary current paths.

39. The current sensor system of claim 37, wherein the primary current path is aligned in parallel with a Z-axis; wherein some of the plurality of magnetic field sensing elements are aligned with their axis of sensitivity parallel to an X-axis, which is orthogonal to the Z-axis; and wherein some of the plurality of magnetic field sensing elements are aligned with their axis of sensitivity parallel to a Y-axis, which is orthogonal to both the X-axis and the Z-axis.

40. A current sensor system comprising:
a primary current path to carry a primary current, comprising
a first inlet pillar;
a second inlet pillar;
an inlet column;
an inlet redistribution layer electrically coupled between the inlet pillars and the inlet column;
a first outlet pillar;
a second outlet pillar;
an outlet column;
an outlet redistribution layer electrically coupled between the outlet pillars and the outlet column; and
an internal conductor electrically coupled between the inlet and outlet columns;
a first magnetic field sensor configured to sense the primary current flowing through the inlet column and the inlet redistribution layer;
a second magnetic field sensor configured to sense the primary current flowing through the outlet column and the outlet redistribution layer; and
a third magnetic field sensor disposed between the inlet column and the outlet column and configured to sense the primary current flowing through the columns and the internal conductor.

41. The current sensor system of claim 40, wherein the columns are aligned in parallel with the pillars; and wherein the redistribution layers are aligned in parallel with the internal conductor.
